(19) United States
(12) Patent Application Publication
(10) Pub. No.: US 2025/0309005 A1
(43) Pub. Date: Oct. 2, 2025

(54) SEMICONDUCTOR WAFER AND METHOD FOR MEASURING SEMICONDUCTOR WAFER

(71) Applicant: HON HAI PRECISION INDUSTRY CO., LTD., New Taipei City (TW)

(72) Inventor: Mu-Chen CHEN, New Taipei City (TW)

(21) Appl. No.: 18/732,649

(22) Filed: Jun. 4, 2024

(30) Foreign Application Priority Data
Apr. 1, 2024 (TW) 113112417

(51) Int. Cl. H01L 21/66

(52) U.S. Cl. CPC H01L 22/14; H01L 22/32

(57) ABSTRACT

A method for measuring a semiconductor wafer includes forming a plurality of metal islands on a backside of a semiconductor layer of the semiconductor wafer. The metal islands have different dimensions, respectively. The metal islands have a plurality of center points arranged equally spaced along an axis. The method further includes sequentially measuring a plurality of current-voltage characteristics between every adjacent two of the metal islands. The method further includes obtaining a specific contact resistance based on the current-voltage characteristics.

### CROSS-REFERENCE TO RELATED APPLICATION

This application claims priority to Taiwan Application Serial Number 113112417, filed Apr. 1, 2024, which is herein incorporated by reference in its entirety.

### BACKGROUND

### Field of Disclosure

The present disclosure relates to a semiconductor wafer and a method for measuring the semiconductor wafer.

### Description of Related Art

Specific contact resistances are important electrical properties of semiconductor wafers. Generally speaking, for thin metallic films, a transmission line model (TLM) is applied for measuring their contact resistances. However, due to current process limitations, it is difficult to measure contact resistances of metallization structures on backsides of the semiconductor wafers using the transmission line model.

Accordingly, how to provide a semiconductor wafer and a method for measuring the semiconductor wafer to solve the aforementioned problems becomes a critical issue to be solved by those in the industry.

### SUMMARY

An aspect of the disclosure is to provide a semiconductor wafer and a method for measuring the semiconductor wafer that may efficiently solve the aforementioned problems.

According to some embodiments of the present disclosure, a method for measuring a semiconductor wafer includes forming a plurality of metal islands on a backside of a semiconductor layer of the semiconductor wafer. The metal islands have different dimensions, respectively. The metal islands have a plurality of center points arranged equally spaced along an axis. The method further includes sequentially measuring a plurality of current-voltage characteristics between every adjacent two of the metal islands. The method further includes obtaining a specific contact resistance based on the current-voltage characteristics.

According to some other embodiments of the present disclosure, a semiconductor wafer includes a semiconductor layer and a metal layer. The semiconductor layer has a frontside and a backside opposite to the frontside. The metal layer is disposed on the backside of the semiconductor layer and has a plurality of metal islands. The metal islands are separated from each other through a plurality of trenches. The metal islands have different dimensions, respectively. The trenches extend through the metal layer into the semiconductor layer and expose a plurality of surfaces and a plurality of sidewalls of the semiconductor layer.

According to yet some other embodiments of the present disclosure, a semiconductor wafer includes a semiconductor layer and a metal layer. The semiconductor layer has a frontside and a backside opposite to the frontside. The metal layer is disposed on the backside of the semiconductor layer and has a plurality of metal islands and a peripheral portion. The metal islands have different dimensions, respectively. The metal islands have a plurality of center points arranged equally spaced along an axis. The peripheral portion surrounds the metal islands and is separated from the metal islands.

Accordingly, in the semiconductor wafer and the method for measuring the semiconductor wafer in some embodiments of the present disclosure, high precision cutting of focused ion beams is performed to define metal islands with different dimensions in the metal layer. As electrical current is provided between every two adjacent metal islands through the probes, total resistances between every two adjacent metal islands are obtained. Then, the specific contact resistance of the semiconductor wafer can be determined. Therefore, measurements of specific contact resistances of metallization structures on the backside of the semiconductor wafer can be achieved.

It is to be understood that both the foregoing general description and the following detailed description are by examples and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a schematic diagram of a backside of a semiconductor wafer according to some embodiments of the present disclosure;

FIG. 1B is a partial cross-sectional view of the semiconductor wafer in FIG. 1A taken along a line A-A according to some embodiments of the present disclosure;

FIG. 2 is a flowchart of a method for measuring the semiconductor wafer according to some embodiments of the present disclosure;

FIG. 3 is a schematic diagram of a current-voltage curve obtained by the method for measuring the semiconductor wafer according to some embodiments of the present disclosure; and

FIG. 4 is a schematic diagram of a linear relationship between total resistances and sums of reciprocals of effective contact areas of metal islands obtained by the method for measuring the semiconductor wafer according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

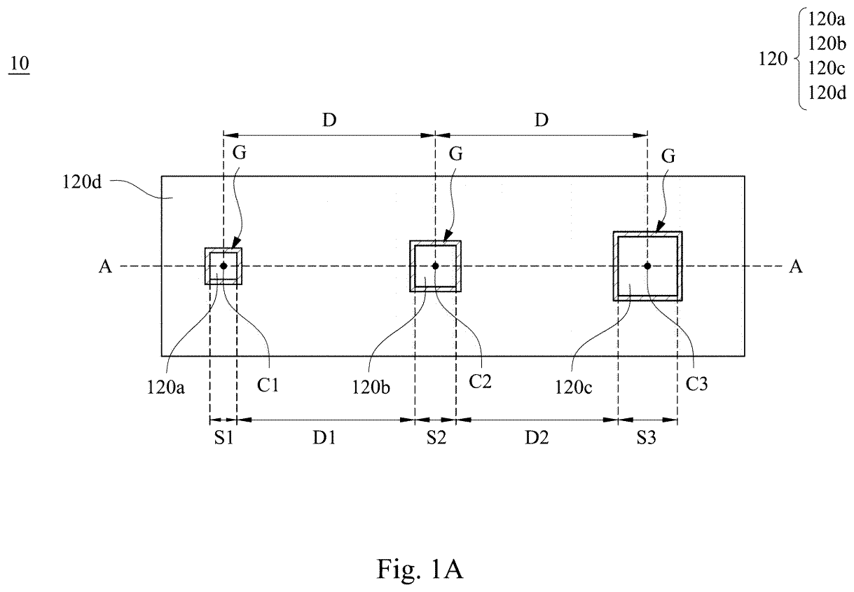

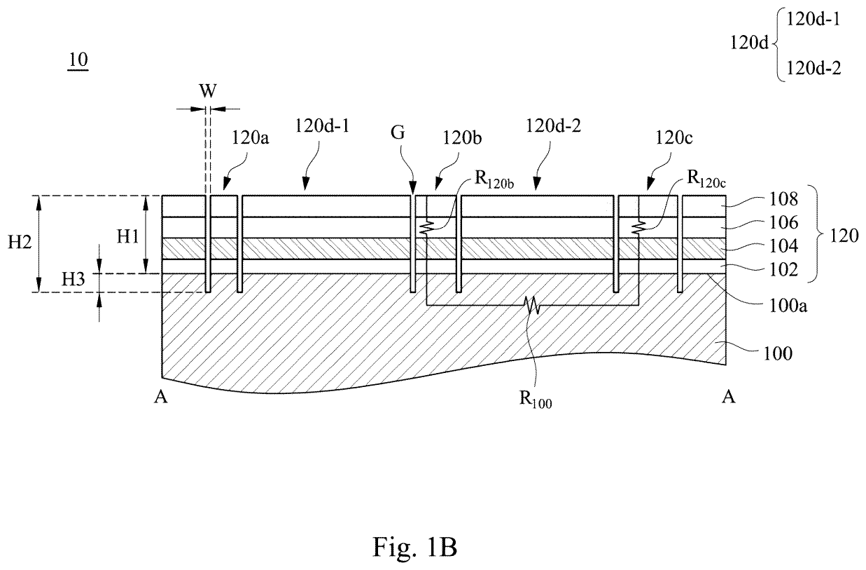

Reference is made to FIG. 1A and FIG. 1B. FIG. 1A is a schematic diagram of a backside of a semiconductor wafer 10 according to some embodiments of the present disclosure. FIG. 1B is a partial cross-sectional view of the semiconductor wafer 10 in FIG. 1A taken along a line A-A according to some embodiments of the present disclosure.

As shown in FIG. 1A and FIG. 1B, the semiconductor wafer 10 includes a semiconductor layer 100 and a metal layer 120. The semiconductor layer 100 has a frontside (not shown) and a backside 100a opposite to the frontside. The frontside of the semiconductor layer 100 may include a plurality of semiconductor components (not shown), but this disclosure is not limited thereto. The metal layer 120 is disposed on the backside 100a of the semiconductor layer 100. In some embodiments, the metal layer 120 includes a contact metal layer 102, a backside metal layer 104, a backside metal layer 106, and a backside metal layer 108. The metal layer 120 has a plurality of metal islands, such as a metal island 120a, a metal island 120b, and a metal island 120c. The metal islands may have arbitrary shapes and different dimensions, respectively. For example, the three metal islands can have different areas, respectively. For example, the three metal islands are substantially square, and the squares have different side lengths, respectively. As shown in FIG. 1A, the metal island 120a has a side length S1, the metal island 120b has a side length S2, and the metal island 120c has a side length S3. In some embodiments, the side length S1 is about 50 microns, the side length S2 is about 75 microns, and the side length S3 is about 100 microns, but this disclosure is not limited thereto.

In addition, center points of the metal islands are arranged equally spaced along an axis. For example, as shown in FIG. 1A, a center point C1 of the metal island 120a, a center point C2 of the metal island 120b, and a center point C3 of the metal island 120c are arranged equally spaced along the line A-A. In other words, a distance D between the center point C1 and the center point C2 is the same as a distance D between the center point C2 and the center point C3. In some embodiments, the distance D is about 300 microns. In some embodiments, since the metal islands may have different side lengths or shapes, respectively, the distances between the boundaries of every two adjacent metal islands may be different. For example, a distance D1 between the metal island 120a and the metal island 120b is greater than a distance D2 between the metal island 120b and the metal island 120c, as shown in FIG. 1A.

The metal layer 120 further includes a peripheral portion 120d. As shown in FIG. 1A, the peripheral portion 120d surrounds the metal islands and is separated from the metal islands. To be more specific, the peripheral portion 120d extends between every two adjacent metal islands. For example, a peripheral portion 120d-1 shown in FIG. 1B is disposed between the metal island 120a and the metal island 120b, and a peripheral portion 120d-2 shown in FIG. 1B is disposed between the metal island 120b and the metal island 120c. The peripheral portion 120d is separated from each of the metal islands by a gap. In other words, the metal layer 120 has a plurality of trenches G through which the metal islands are separated from each other and are separated from the peripheral portion 120d. In some embodiments, as shown in FIG. 1B, a width W of the trenches G is about 5 microns, but this disclosure is not limited thereto. In some embodiments, the metal layer 120 is cut, for example, through focused ion beams (FIB), to form the metal islands, and the peripheral portion 120d is a remaining portion of the metal layer 120 after the cutting is completed.

Next, as shown in FIG. 1B, in some embodiments, the trenches G extend through the metal layer 120 into the semiconductor layer 100 and exposes a plurality of surfaces and sidewalls of the semiconductor layer 100. In some embodiments, a thickness H1 of the metal layer 120 is about 3 microns, and a depth H2 of the trenches G is about 4 microns. In other words, a depth H3 of the trenches G recessed from the backside into the semiconductor layer 100 is about 1 micron. However, this disclosure is not limited thereto.

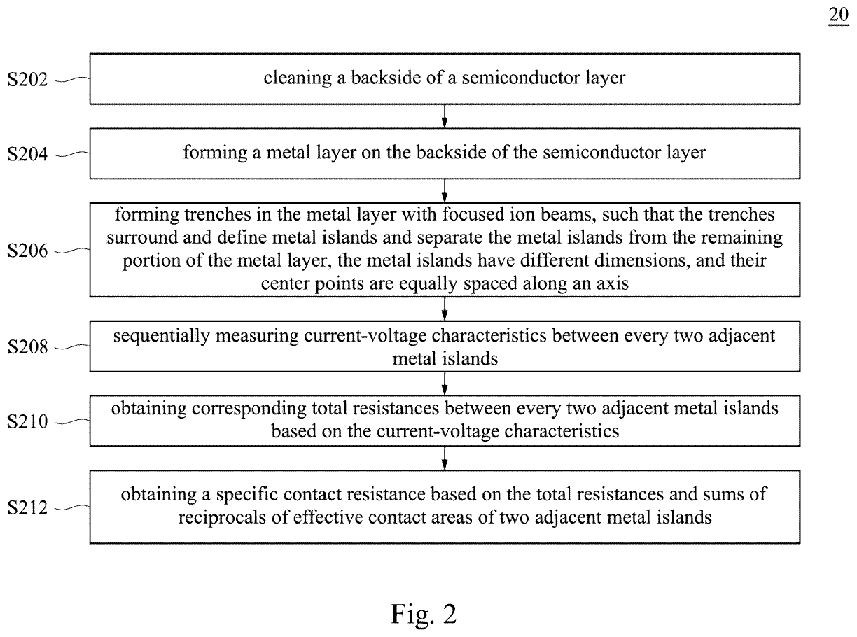

Reference is made to FIG. 2. FIG. 2 is a flowchart of a method 20 for measuring a semiconductor wafer according to some embodiments of the present disclosure. As shown in FIG. 2, the method 20 includes steps S202 to S212. In brief, the step S202 is the preprocessing of a backside of the semiconductor wafer. The steps S204 to S206 form a plurality of metal islands on the backside of the semiconductor wafer. The steps S208 to S212 obtain a specific contact resistance of the semiconductor wafer through measuring the electrical properties of the metal islands.

In greater detail, in the step S202, the backside of the semiconductor layer is cleaned. Next, the step S204 includes forming a metal layer on the backside of the semiconductor layer. In the step S206, trenches are formed in the metal layer with focused ion beams, such that the trenches surround and define metal islands and separate the metal islands from the remaining portion of the metal layer. The metal islands have different dimensions (such as areas), respectively. The metal islands have center points that are arranged equally spaced along an axis. As aforementioned, the trenches extend through the metal layer into the semiconductor layer and exposes surfaces and sidewalls of the semiconductor layer. Next, the step S208 includes sequentially measuring current-voltage characteristics between every two adjacent metal islands. For example, a current-voltage curve (i.e., an I-V curve) of the metal island 120a and the metal island 120b and a current-voltage curve of the metal island 120b and the metal island 120c are obtained. Next, in the step S210, total resistances between every two adjacent metal islands are obtained based on the current-voltage characteristics. For example, a total resistance between the metal island 120a and the metal island 120b is obtained by measuring a slope of a regression line of the current-voltage curve of the metal island 120a and the metal island 120b. Similarly, a total resistance between the metal island 120b and the metal island 120c is obtained by measuring a slope of a regression line of the current-voltage curve of the metal island 120b and the metal island 120c. Next, the step S212 includes obtaining a specific contact resistance based on the total resistances obtained in the step S210 and effective contact areas of the metal islands. For example, in the step S212, a regression line of the total resistances on sums of reciprocals of the effective contact areas of the corresponding metal islands is obtained. Then, a slope of the regression line can be taken as the specific contact resistance.

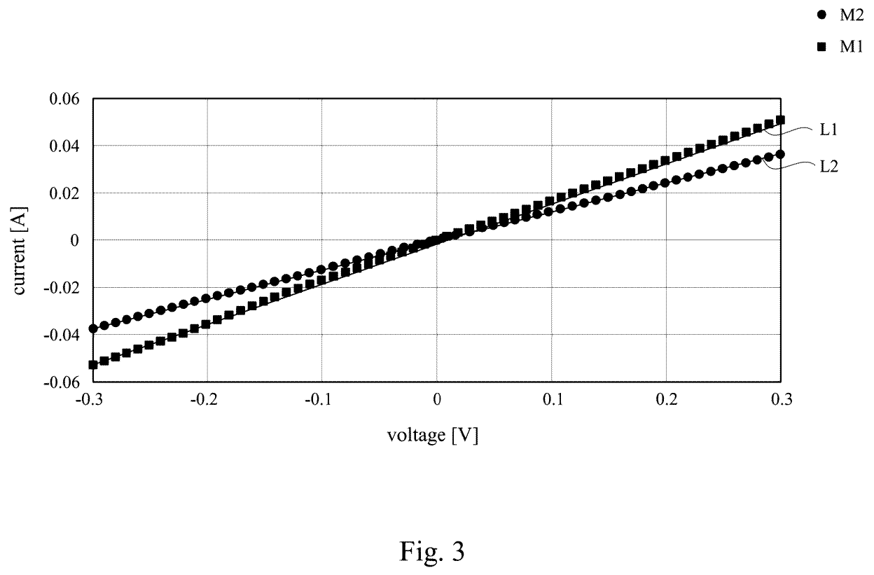

Reference is made to FIG. 3. FIG. 3 is a schematic diagram of a current-voltage curve obtained by the method 20 according to some embodiments of the present disclosure. In the step S208, different electrical currents are provided to the probes for measuring their corresponding voltages. When the probes are respectively disposed on the metal island 120a and the metal island 120b, a data set M1 is obtained. When the probes are respectively disposed on the metal island 120b and the metal island 120c, a data set M2 is obtained. Next, in the step S210, a linear relationship of each data set is obtained using a first-order linear regression model. For example, a line equation of a regression line L1 of the data set M1 is I=0.0818V+0.0004, where I represents the electrical current flows through the probes, and V is the measured voltage. Similarly, a line equation of a regression line L2 of the data set M2 is I=0.1225V−0.0005. Accordingly, a total resistance determined through the data set M1 is 1/0.0818˜12.22(Ω), and a total resistance determined through the data set M2 is 1/0.1225˜8.16(Ω). The total resistance herein includes resistances and contact resistances of the probes, resistances and the contact resistances of two adjacent metal islands, and a resistance of a portion of the semiconductor layer 100 through which the electrical current flows during measurement. For example, referring back to FIG. 1B, the total resistance at least includes the resistance R120b, the resistance R120c, and the resistance R100.

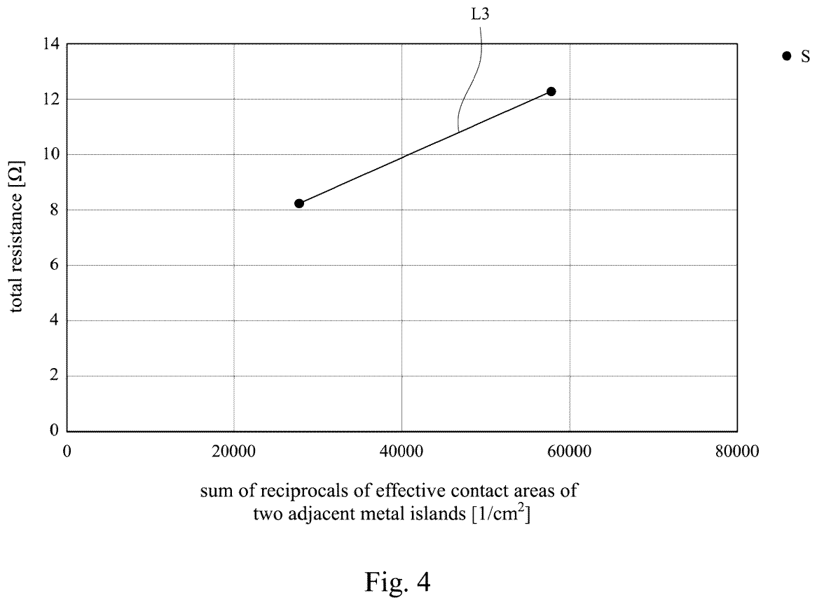

Next, reference is made to FIG. 4. FIG. 4 is a schematic diagram of a linear relationship between the total resistances obtained in the aforementioned steps of the method 20 and sums of reciprocals of the effective contact areas of the metal islands according to some embodiments of the present disclosure. In some embodiments, the contact resistances and the resistances of the probes remain substantially unchanged. Since the resistances of the metal islands are inversely proportional to the thickness of the metal islands, when the thicknesses of the metal islands are substantially the same (for example, the metal layer 120 in FIG. 1B has a uniform thickness), the resistances of the metal islands are substantially the same. The resistance of the portion of the semiconductor layer 100 through which the electrical current flows during measurement is inversely proportional to a length of the current path. When distances between the center points of every two adjacent metal islands are substantially the same, the lengths of the current paths between every two adjacent metal islands are substantially the same. Thus, the resistance of the portion of the semiconductor layer 100 remains substantially the same during measurement. At the same time, the specific contact resistance is the contact resistance per unit area. When measurements are conducted on the same semiconductor wafer, the specific contact resistance is a substantially constant value. As a result, the total resistance is substantially a one-variable function of the sum of the reciprocals of the effective contact areas of two adjacent metal islands. In this way, the linear relationship between the total resistances and the sums of the reciprocals of the effective contact areas may be determined in the step S212. For example, a straight line or a regression line may be determined. Then, the slope of the straight line or the regression line can be taken as the specific contact resistance of the semiconductor wafer. For example, as shown in FIG. 4, the data set S includes the total resistances and the sums of the reciprocals of the effective contact areas of the metal islands from the data set M1 and the data set M2. The line equation of the straight line L3 of the data set S is Rₜ=0.000135S+4.400741, where Rₜ is the total resistance, and S represents the sums of the reciprocals of the effective contact areas of two adjacent metal islands. Therefore, the specific contact resistance of the semiconductor wafer is 0.000135 (Ω-cm²). In some embodiments, more than three metal islands can be defined. As a result, a first-order linear regression model may be used to obtain a regression line between total resistances and sums of reciprocals of effective contact areas corresponding to more than two data sets and a slope of the regression line is the specific contact resistance.

In semiconductor fabrication, after a wafer is diced, some incomplete dies (i.e., edge dies or ugly dies) may be formed around edges of the wafer. Therefore, with the method disclosed in the present disclosure, the different effective contact areas of the incomplete dies and complete dies can be exploited to measure the specific contact resistance of the wafer.

According to the foregoing recitations of the embodiments of the disclosure, it may be seen that in the semiconductor wafer and the method for measuring the semiconductor wafer in some embodiments of the present disclosure, high precision cutting of focused ion beams is performed to define metal islands with different dimensions in the metal layer. As electrical current is provided between every two adjacent metal islands through the probes, total resistances between every two adjacent metal islands are obtained. Then, the specific contact resistance of the semiconductor wafer can be determined. Therefore, measurements of specific contact resistances of metallization structures on the backside of the semiconductor wafer can be achieved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A method for measuring a semiconductor wafer, comprising:
forming a plurality of metal islands on a backside of a semiconductor layer of the semiconductor wafer, wherein the metal islands have different dimensions, respectively, and the metal islands have a plurality of center points arranged equally spaced along an axis;
sequentially measuring a plurality of current-voltage characteristics between every adjacent two of the metal islands; and
obtaining a specific contact resistance of the metal islands based on the current-voltage characteristics.

2. The method according to claim 1, wherein forming the metal islands comprises:
forming a metal layer on the backside of the semiconductor layer; and
forming a plurality of trenches in the metal layer, wherein the trenches surround and define the metal islands and separate the metal islands from a remaining portion of the metal layer.

3. The method according to claim 2, wherein forming the trenches in the metal layer is performed through focused ion beams.

4. The method according to claim 2, wherein the trenches extend through the metal layer into the semiconductor layer and expose a plurality of surfaces of the semiconductor layer.

5. The method according to claim 4, wherein the trenches extend from the backside by a depth into the semiconductor layer, and the depth is about 1 micron.

6. The method according to claim 1, wherein obtaining the specific contact resistance of the metal islands based on the current-voltage characteristics comprises:
obtaining a plurality of resistances between every adjacent two of the metal islands based on the current-voltage characteristics; and
obtaining the specific contact resistance of the metal islands based on the resistances and a plurality of effective contact areas of the metal islands.

7. A semiconductor wafer, comprising:
a semiconductor layer having a frontside and a backside opposite to the frontside; and
a metal layer disposed on the backside of the semiconductor layer and having a plurality of metal islands, wherein the metal islands are separated from each other through a plurality of trenches, the metal islands have different dimensions, respectively, and the trenches extend through the metal layer into the semiconductor layer and expose a plurality of surfaces and a plurality of sidewalls of the semiconductor layer.

8. The semiconductor wafer according to claim 7, wherein each of the trenches has a width of about 5 microns.

9. The semiconductor wafer according to claim 7, wherein each of the trenches has a depth of about 4 microns.

10. The semiconductor wafer according to claim 7, wherein the metal islands have a plurality of center points arranged equally spaced along an axis.

11. The semiconductor wafer according to claim 7, wherein the metal islands comprise three metal islands that are substantially square, and a plurality of side lengths of the three metal islands are about 50 microns, about 75 microns, and about 100 microns, respectively.

12. The semiconductor wafer according to claim 7, wherein the metal layer has a thickness of about 3 microns.

13. A semiconductor wafer, comprising:
a semiconductor layer having a frontside and a backside opposite to the frontside; and
a metal layer disposed on the backside of the semiconductor layer and having a plurality of metal islands and a peripheral portion, wherein the metal islands have different dimensions, respectively, and the metal islands have a plurality of center points arranged equally spaced along an axis, and the peripheral portion surrounds the metal islands and is separated from the metal islands.

14. The semiconductor wafer according to claim 13, wherein a distance between every adjacent two of the center points along the axis is about 300 microns.

15. The semiconductor wafer according to claim 13, wherein the peripheral portion extends between every adjacent two of the metal islands, and the peripheral portion is separated from each of the metal islands by a gap.

16. The semiconductor wafer according to claim 15, wherein the gap has a width of about 5 microns.

17. The semiconductor wafer according to claim 13, wherein the semiconductor layer has a plurality of trenches recessed from the backside, and a plurality of surfaces and a plurality of sidewalls of the semiconductor layer are exposed through the metal layer and the trenches.

18. The semiconductor wafer according to claim 17, wherein each of the trenches has a depth of about 1 micron.

19. The semiconductor wafer according to claim 17, wherein each of the trenches has a width of about 5 microns.

20. The semiconductor wafer according to claim 13, wherein the peripheral portion and the metal islands have a thickness of about 3 microns.
